(19) United States
(12) Patent Application Publication
(10) Pub. No.: US 2024/0347589 A1
(43) Pub. Date: Oct. 17, 2024

(54) SEMICONDUCTOR DEVICE

(71) Applicant: SAMSUNG ELECTRONICS CO., LTD., SUWON-SI (KR)

(72) Inventors: Youngsoo SONG, SUWON-SI (KR); Suhyeon KIM, SUWON-SI (KR); Rooli CHOI, SUWON-SI (KR); Jihoon PARK, SUWON-SI (KR)

(21) Appl. No.: 18/633,791

(22) Filed: Apr. 12, 2024

(30) Foreign Application Priority Data
Apr. 17, 2023 (KR) 10-2023-0049987

(51) Int. Cl. H01L 29/06; H01L 27/02; H01L 27/092; H01L 29/08; H01L 29/423; H01L 29/66; H01L 29/775; H01L 29/786

(52) U.S. Cl. CPC H01L 29/0649; H01L 27/0207; H01L 27/092; H01L 29/0673; H01L 29/0847; H01L 29/42392; H01L 29/66439; H01L 29/775; H01L 29/78696

(57) ABSTRACT

A semiconductor device includes an active region on a substrate and an active pattern extending in a first direction. A device isolation layer surrounds the active pattern. A gate structure extends in a second direction. A source/drain region is on the active pattern. An interlayer insulating layer covers the source/drain region. A contact structure is connected to the source/drain region. A buried conductive structure extends in the first direction, is electrically connected to the contact structure, and passes through the interlayer insulating layer to extend in a third direction. A power delivery structure extends from a lower surface of the substrate towards an upper surface thereof, and is electrically connected to the buried conductive structure. The buried conductive structure includes a body portion extending in the first direction, and an extension portion extending from a region of at least one side surface of the body portion in the second direction.

### CROSS-REFERENCE TO RELATED APPLICATION(S)

This application claims priority under 35 U.S.C. § 119 to Korean Patent Application No. 10-2023-0049987, filed on Apr. 17, 2023 in the Korean Intellectual Property Office, the disclosure of which is incorporated by reference in its entirety herein.

### TECHNICAL FIELD

The present inventive concept relates to a semiconductor device.

### DISCUSSION OF RELATED ART

As consumer demand for high performance, high speed, and multifunctionality of semiconductor devices increases, the integration level of semiconductor devices has also increased. The high integration level of a semiconductor device may be implemented by patterns having a fine width or a fine distance. In addition, a semiconductor device having a back side power delivery network (BSPDN) structure in which a power rail is on a rear surface of a wafer is being developed to increase the degree of integration of the semiconductor device.

### SUMMARY

An aspect of the present inventive concept is to provide a semiconductor device securing a contact margin between a buried conductive structure and a power delivery structure.

According to an embodiment of the present inventive concept, a semiconductor device includes a substrate. An active region is on the substrate and includes an active pattern extending in a first direction. A device isolation layer is on the substrate. The device isolation layer surrounds the active pattern. A gate structure extends in a second direction intersecting the first direction. A source/drain region is disposed on the active pattern on both sides of the gate structure. An interlayer insulating layer is on the device isolation layer. The interlayer insulating layer at least partially covers the gate structure and the source/drain region. A contact structure passes through the interlayer insulating layer. The contact structure is connected to the source/drain region. A buried conductive structure extends in the first direction. The buried conductive structure is electrically connected to the contact structure. The buried conductive structure passes through the interlayer insulating layer and the device isolation layer to extend in a third direction perpendicular to the first and second directions. A power delivery structure extends from a lower surface of the substrate towards an upper surface of the substrate. The power delivery structure is electrically connected to the buried conductive structure. The buried conductive structure includes a body portion extending in the first direction, and an extension portion extending from a region of at least one side surface of the body portion in the second direction towards the active pattern.

According to an embodiment of the present inventive concept, a semiconductor device includes a substrate. A first active pattern and a second active pattern are on the substrate. The first and second active patterns extend in a first direction. A device isolation layer is on the substrate. The device isolation layer surrounds the first and second active patterns. A gate structure extends in a second direction intersecting the first direction. A first source/drain region is on the first active pattern on both sides of the gate structure. A second source/drain region is on the second active pattern on both sides of the gate structure. An interlayer insulating layer is on the device isolation layer. The interlayer insulating layer at least partially covers the gate structure and the first and second source/drain regions. A contact structure passes through the interlayer insulating layer. The contact structure is connected to each of the first and second source/drain regions. A buried conductive structure extends in the first direction. The buried conductive structure is connected to the contact structure. The buried conductive structure passes through at least a portion of the interlayer insulating layer and at least a portion of the device isolation layer to extend in a third direction perpendicular to the first and second directions. A power delivery structure extends from a lower surface of the substrate towards an upper surface of the substrate. The power delivery structure is electrically connected to the buried conductive structure. At least one of the first active pattern or the second active pattern includes a first active portion having a first width and a second active portion having a second width greater than the first width. The buried conductive structure includes a first extension portion extending towards the first active portion. The first extension portion extends in the third direction and is connected to the power delivery structure.

According to an embodiment of the present inventive concept, a semiconductor device includes a substrate. An active region extends on the substrate in a first direction. The active region includes an active pattern. A device isolation layer is on the substrate. The device isolation layer surrounds the active pattern. A plurality of channel layers is stacked on the active pattern. Each of the plurality of channel layers are spaced apart from each other. A gate structure is on the active pattern. The gate structure extends in a second direction intersecting the first direction. The gate structure surrounds the plurality of channel layers. A source/drain region is on the active pattern on both sides of the gate structure. An interlayer insulating layer is on the device isolation layer. The interlayer insulating layer at least partially covers the gate structure and the source/drain region. A contact structure passes through the interlayer insulating layer. The contact structure is connected to the source/drain region. A buried conductive structure extends in the first direction. The buried conductive structure is connected to the contact structure. The buried conductive structure passes through at least a portion of the interlayer insulating layer and at least a portion of the device isolation layer. A power delivery structure extends from a lower surface of the substrate towards an upper surface of the substrate. The power delivery structure is electrically connected to the buried conductive structure. The buried conductive structure extends in a third direction perpendicular to the first and second directions. The buried conductive structure includes a first region having a minimum width and a second region having a width greater than the minimum width. The buried conductive structure is connected to the power delivery structure in the second region. The active pattern adjacent to the buried conductive structure includes a protruding portion protruding towards the first region.

### BRIEF DESCRIPTION OF DRAWINGS

The above and other aspects, features, and advantages of embodiments of the present inventive concept will be more clearly understood from the following detailed description, taken in conjunction with the accompanying drawings, in which:

FIG. 1A is a layout diagram of a semiconductor device according to an embodiment of the present inventive concept.

FIG. 1B is a plan view of a semiconductor device taken from portion A of FIG. 1A according to an embodiment of the present inventive concept.

FIG. 2A illustrates cross-sectional views of a semiconductor device taken along lines I-I′ and II-II′ of FIG. 1B according to embodiments of the present inventive concept.

FIGS. 2B, 2C and 2D are perspective views illustrating some components of a semiconductor device according to embodiments of the present inventive concept.

FIGS. 3 and 4A are plan views of semiconductor devices according to embodiments of the present inventive concept.

FIGS. 4B and 4C are perspective views illustrating some components of semiconductor devices according to embodiments of the present inventive concept.

FIG. 5A is a plan view of a semiconductor device according to an embodiment of the present inventive concept.

FIGS. 5B and 5C are perspective views illustrating some components of semiconductor devices according to embodiments of the present inventive concept.

FIG. 6 are cross-sectional views taken along lines I-I′ and II-II′ of FIG. 1B illustrating a semiconductor device according to embodiments of the present inventive concept.

FIGS. 7A, 7B, 7C, 7D, and 7E are cross-sectional views taken along line I-I′ of FIG. 1B illustrating a method of manufacturing a semiconductor device in a process sequence according to embodiments of the present inventive concept.

### DETAILED DESCRIPTION OF EMBODIMENTS

Hereinafter, embodiments will be described with reference to the accompanying drawings. Hereinafter, it can be understood that terms such as ‘on,’ ‘upper,’ ‘upper portion,’ ‘upper surface,’ ‘below,’ ‘lower,’ ‘lower portion,’ ‘lower surface,’ ‘side surface,’ and the like may be denoted by reference numerals and refer to the drawings, except where otherwise indicated.

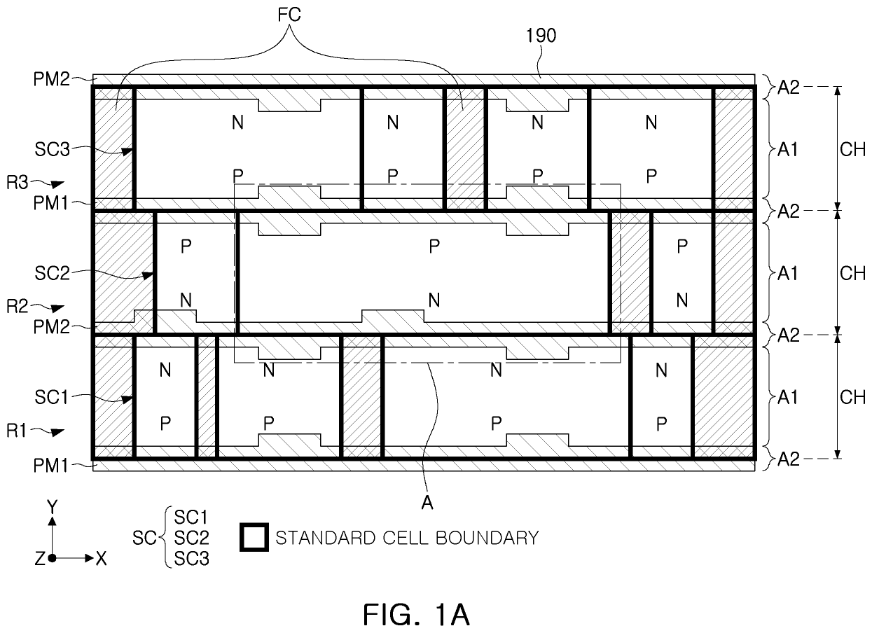

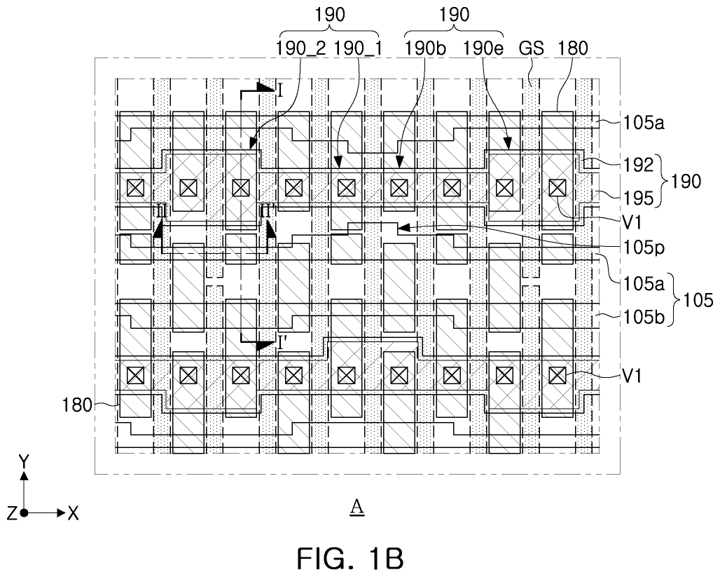

FIG. 1A is a layout diagram of a semiconductor device according to an embodiment.

Referring to FIG. 1A, a semiconductor device 100 according to an embodiment may include standard cells SC and filler cells FC serving as dummy regions. In an embodiment, each of the standard cells SC may extend in a first direction (e.g., the X direction), and may be arranged in three (3) rows arranged in a second direction (e.g., the Y direction), perpendicular to the first direction X.

As shown in FIG. 1A, first to third standard cells SC1, SC2, and SC3 respectively arranged in first to third rows R1, R2, and R3 may have a cell height CH defined in the second direction (e.g., the Y direction). However, embodiments of the present inventive concept are not necessarily limited thereto and the number of the standard cells may vary. The first to third standard cells SC1, SC2, and SC3 disposed in the same row may have the same cell height CH as each other (e.g., length in the Y direction. However, embodiments of the present inventive concept are not necessarily limited thereto. A plurality of standard cells, such as the first to third standard cells SC1, SC2, and SC3, may have different widths (e.g., lengths in the first direction X), even though they are located on the same row.

The plurality of standard cells, such as the first to third standard cells SC1, SC2, and SC3, may include a first conductivity type (e.g., P-type) active region and a second conductivity type (e.g., N-type) active region, arranged in a direction of the rows, e.g., in the second direction Y. The first to third standard cells SC1, SC2, and SC3 located on two adjacent rows, among the first to third rows R1, R2, and R3, may be arranged such that active regions of the same conductivity type are adjacent to each other. For example, the second and third standard cells SC2 and SC3 of the second and third rows R2 and R3 may be arranged such that the P-type active regions are adjacent to each other (e.g., in the Y direction), and the first and second standard cells SC1 and SC2 of the first and second rows R1 and R2 may be arranged such that the N-type active regions are adjacent to each other (e.g., in the Y direction).

A plurality of first and second power lines PM1 and PM2 supplying power to the plurality of standard cells, such as the first to third standard cells SC1, SC2 and SC3, may extend along boundaries of the plurality of standard cells SC1 and SC2 in the first direction X, respectively. Each of the plurality of first and second power lines PM1 and PM2 may supply different potentials to the first to third standard cells SC1, SC2, and SC3 located therebetween. Among the plurality of first and second power lines PM1 and PM2, a power line disposed on a boundary between standard cells in two adjacent rows may be a shared power line shared by adjacent standard cells.

As illustrated in FIG. 1A, the plurality of first power lines PM1 may be disposed on an outer boundary adjacent to a P-type active region (e.g., a lower boundary of the first row R1 and an upper boundary of the second row R2) and a boundary between adjacent P-type active regions (e.g., between the second row R2 and the third row R3), and the plurality of second power supply lines PM2 may be disposed on an outer boundary adjacent to an N-type active region, and a boundary between adjacent N-type device regions (e.g., between the first row RI and the second row R2). However, embodiments of the present inventive concept are not necessarily limited thereto. The first power lines PM1 and the second power lines PM2 may be alternately arranged in a column direction, e.g., in the second direction Y.

In an embodiment, a first area A1 may be a cell region in which cells are formed, and a second area A2 may be a power rail region in which a power rail for applying various voltages such as a source voltage, a drain voltage, a ground voltage, and the like to the cells, is formed. In an embodiment, the second area A2 may extend in the first direction X, and may be formed in plural to be spaced apart from each other in the second direction Y.

The first area A1 may be disposed between and connected to second areas A2. For example, both ends of the first area A1 in the second direction Y may be respectively connected to (e.g., directly connected thereto) the second areas A2. In an embodiment, the first area A1 may include a plurality of cell regions disposed in the first direction X and connected to each other. The number of cell regions is not necessarily limited to that shown in the drawings. Hereinafter, each of the first and second regions Al and A2 may be defined as including not only a substrate 101 but also upper and lower spaces corresponding thereto. In an embodiment, the first area A1 may include a PMOS region and an NMOS region, which may be spaced apart from each other in the second direction Y.

FIG. 1B is a schematic plan view of a semiconductor device according to an embodiment. A semiconductor device 100 according to an embodiment may be one “standard cell” indicated by portion “A” in the layout of FIG. 1A.

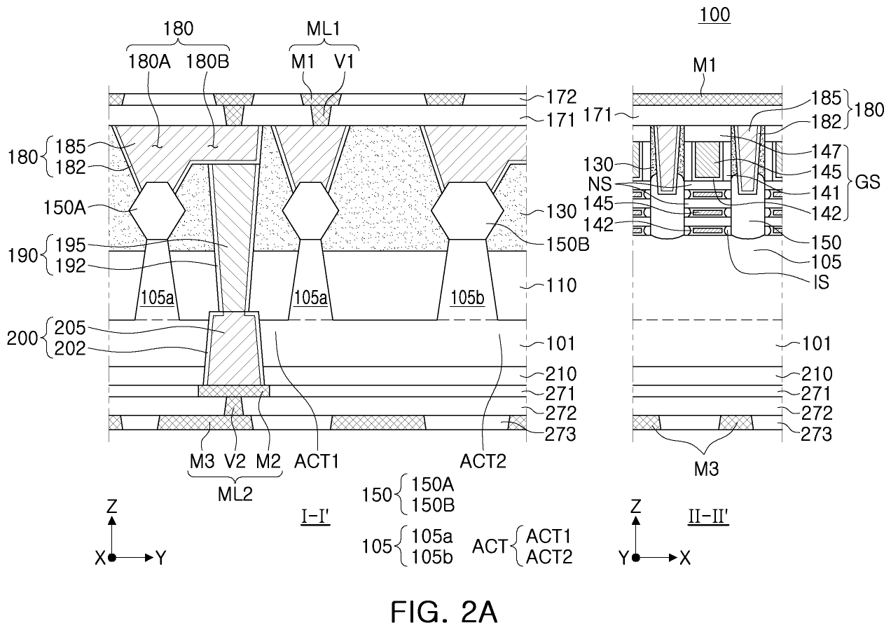

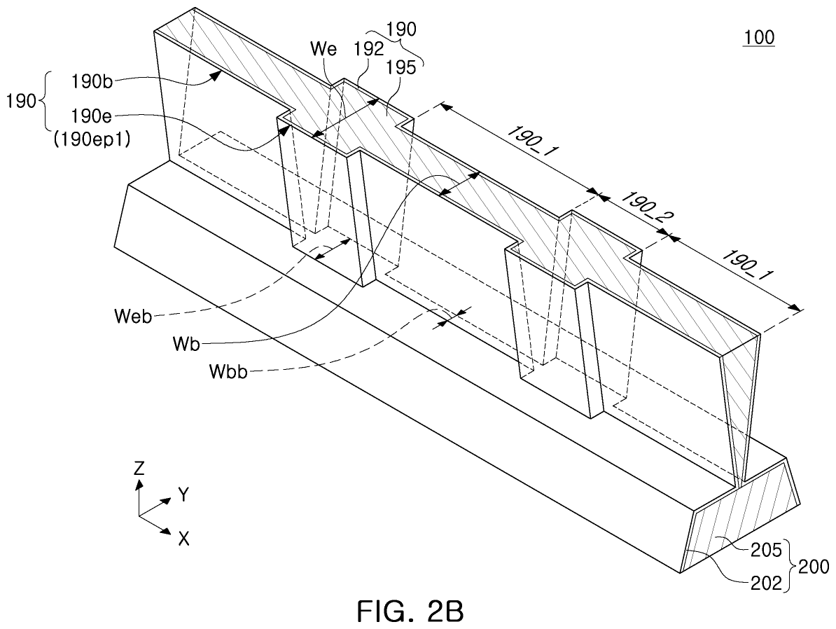

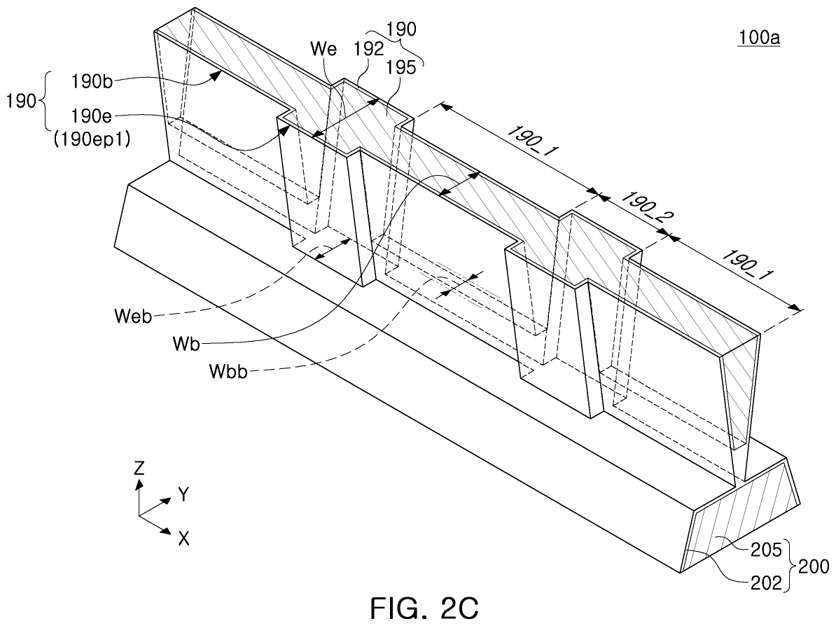

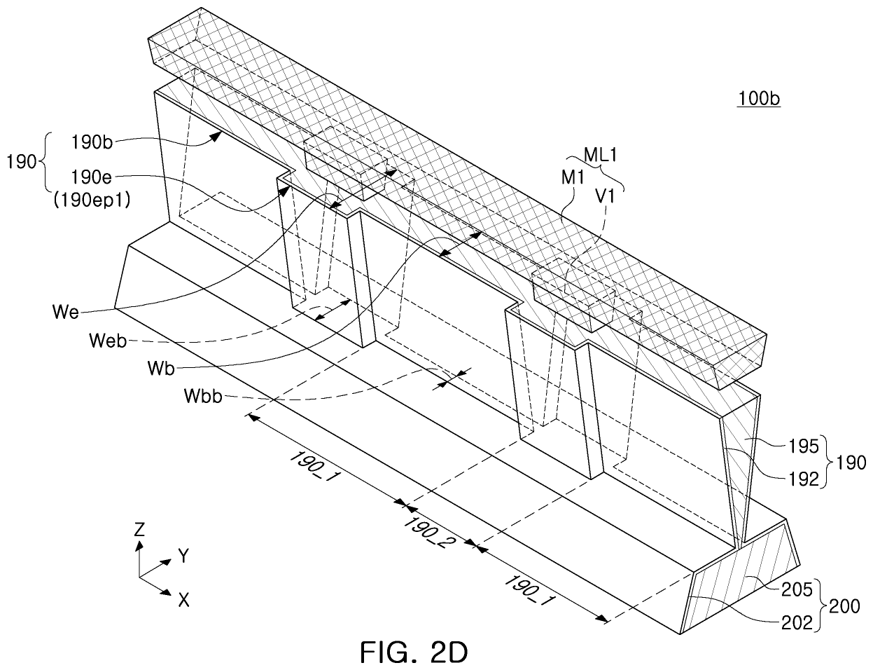

FIG. 2A illustrates schematic cross-sectional views of a semiconductor device according to an embodiment. FIG. 2A illustrates cross-sectional views of the semiconductor device of FIG. 1B taken along lines I-I′ and II-II′, respectively. For convenience of description, only some components of the semiconductor device may be illustrated in FIG. 1B.

FIG. 2B is a perspective view schematically illustrating some components of a semiconductor device according to an embodiment. FIG. 2B illustrates schematic perspective views of a buried conductive structure 190 and a power delivery structure 200.

Referring to FIGS. 1B to 2B, a semiconductor device 100 according to an embodiment may include a substrate 101 including an active region ACT, the active region ACT on an upper surface of the substrate 101 and including an active pattern 105 extending in the first direction X, a device isolation layer 110 surrounding the active pattern 105, a gate structure GS extending in the second direction Y intersecting the first direction X and crossing the active pattern 105, a source/drain region 150 disposed on the active pattern 105 on both sides of the gate structure GS, an interlayer insulating layer 130 covering the gate structure GS and the source/drain region 150, a contact structure 180 connected to the source/drain region 150, a buried conductive structure 190 connected to the contact structure 180, and a power delivery structure 200 connected to a lower surface of the buried conductive structure 190. In an embodiment, the semiconductor device 100 may further include a plurality of channel layers NS, a lower interlayer insulating layer 210, a first interconnection portion ML1, and a second interconnection portion ML2.

The substrate 101 may have an upper surface extending in the X and Y directions. In an embodiment, the substrate 101 may include a semiconductor material, for example, a group IV semiconductor, a group III-V compound semiconductor, or a group II-VI compound semiconductor. For example, the group IV semiconductor may include silicon, germanium, or silicon-germanium. The substrate 101 may be provided as a bulk wafer, an epitaxial layer, a silicon-on-insulator (SOI) layer, a semiconductor-on-insulator (SeOI) layer, or the like. However, embodiments of the present inventive concept are not necessarily limited thereto.

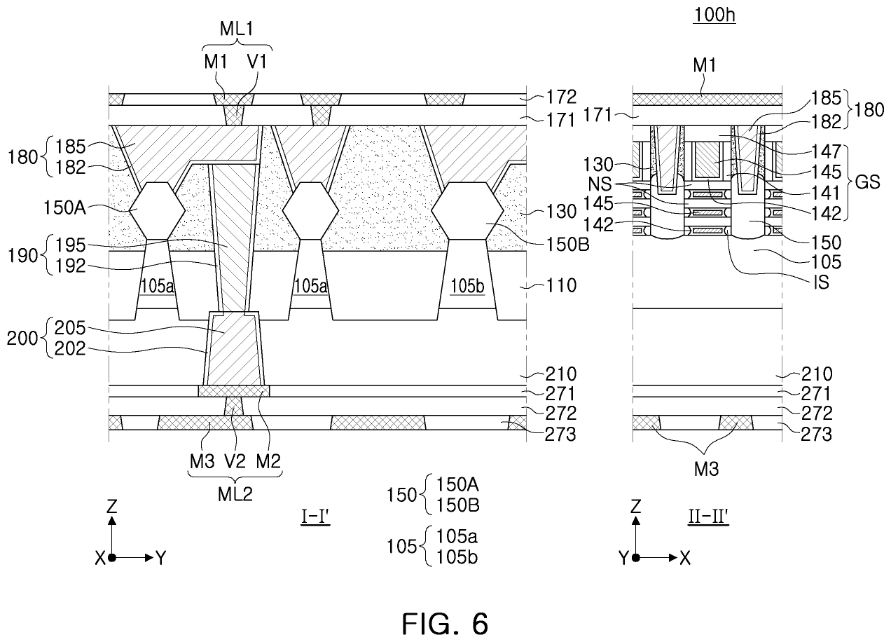

The substrate 101 may include active patterns 105 disposed thereon. The active patterns 105 may also be described as a separate configuration from the substrate 101. According to an embodiment, the substrate 101 below the active patterns 105 may be removed (see FIG. 6).

The active regions ACT may be disposed to extend in the first direction, for example, the X direction. The active regions ACT may be defined as having a predetermined depth from an upper surface in a portion of the substrate 101. In an embodiment, the active regions ACT may be formed as a portion of the substrate 101, or may include an epitaxial layer grown from the substrate 101. Each of the active regions ACT may include active patterns 105, which may be active fins protruding in an upward direction (e.g., the Z direction). According to an embodiment, the active region ACT may include a first active region ACT1 and a second active region ACT2. The first active region ACT1 may have a first active pattern 105a, and the second active region ACT2 may have a second active pattern 105b. For example, a width of the first active pattern 105a may be different from a width of the second active pattern 105b.

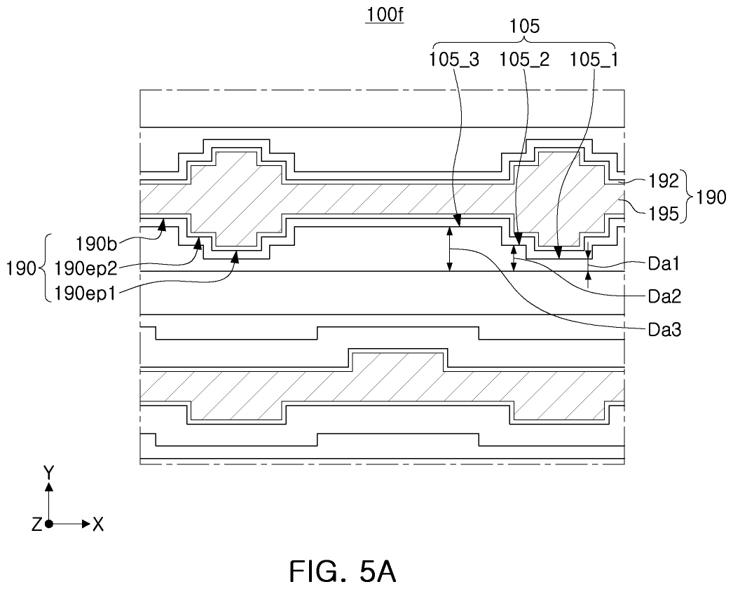

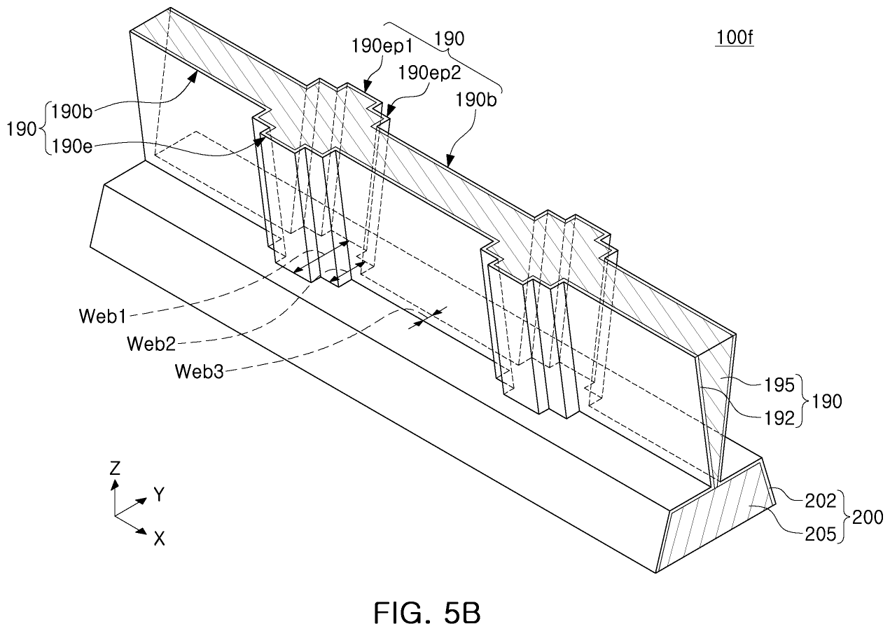

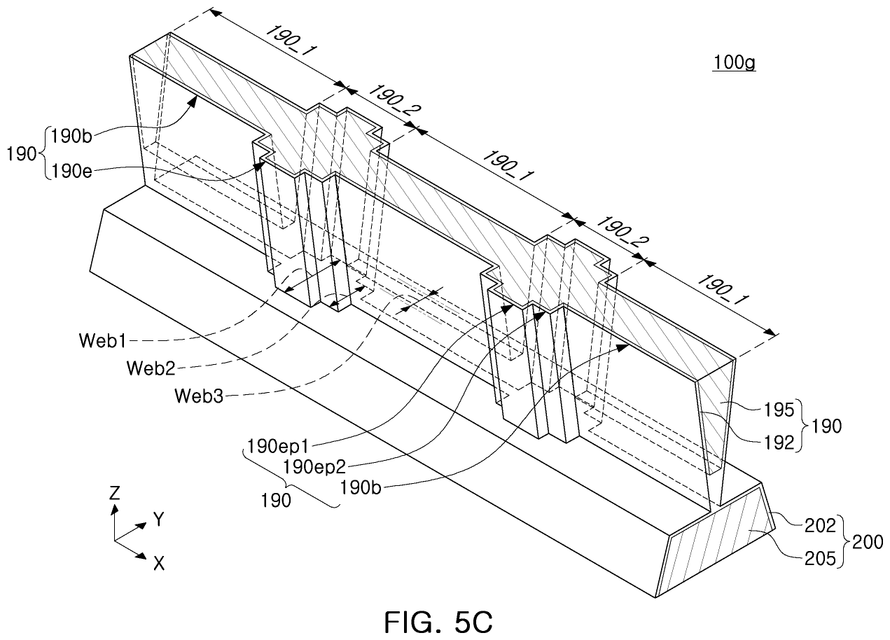

According to an embodiment, at least one of the first active pattern 105a or the second active pattern 105b may include a first active portion 105_1 having a first width Da1 (e.g., length in the Y direction), and a second active portion 105_2 having a second width Da2 (e.g., length in the Y direction) greater than the first width Da1 (see FIG. 5A).

According to an embodiment, at least one of the first active pattern 105a or the second active pattern 105b may further include a third active portion 105_3 having a third width Da3 (e.g., length in the Y direction), greater than the second width Da2 (see FIG. 5A).

According to an embodiment, a first side surface of the first active pattern 105a and a first side surface of the second active pattern 105b may be relatively flat, and a second side surface of the first active pattern 105a, opposite to the first side surface of the first active pattern 105a, and a second side surface of the second active pattern 105b, opposite to the first side surface of the second active pattern 105b, may include a curved portion, respectively.

According to an embodiment, each of the active patterns 105 may have a portion curved towards the buried conductive structure 190 closest to each of the active patterns 105, and may have a portion curved toward adjacent active patterns 105. For example, the first active pattern 105a may have a portion curved towards the buried conductive structure 190 closest to the first active pattern 105a, and may have a portion curved towards the second active pattern 105b. For this reason, the buried conductive structure 190 may include an extension portion 190e extending towards a portion in which a width of the active patterns 105 is minimized (e.g., reduced), and a contact margin with the power delivery structure 200 may be secured.

As illustrated in FIG. 1B, the active pattern 105 may have a portion curved towards (e.g., extending towards) the buried conductive structure 190. The active patterns 105 together with the plurality of channel layers NS may constitute an active structure in which a channel region of a transistor is formed. Each of the active regions ACT may include an impurity region. The impurity region may form at least a portion of a well region of the transistor.

The device isolation layer 110 may be disposed between adjacent active patterns 105 in the Y direction. Upper surfaces of the active patterns 105 may be positioned at a higher level than an upper surface of the device isolation layer 110.

The device isolation layer 110 may fill between the active patterns 105, and may define the active regions ACT including the active patterns 105 on the substrate 101. In an embodiment, the device isolation layer 110 may be formed by, for example, a shallow trench isolation (STI) process. The device isolation layer 110 may expose an upper surface of the active region ACT, or may partially expose an upper portion of the active region ACT. The device isolation layer 110 may be formed of an insulating material. In an embodiment, the device isolation layer 110 may include, for example, an oxide, a nitride, or a combination thereof. However, embodiments of the present inventive concept are not necessarily limited thereto.

The gate structure GS may have a linear shape extending in the second direction Y. The gate structure GS may be disposed in one region of the active pattern 105. As illustrated in FIG. 2A, the gate structure GS may include gate spacers 141, a gate dielectric layer 142 and a gate electrode 145, sequentially disposed between the gate spacers 141, and a gate capping layer 147 disposed on the gate electrode 145. For example, in an embodiment the gate spacers 141 may include an insulating material such as SiOCN, SiON, SiCN, or SiN. However, embodiments of the present inventive concept are not necessarily limited thereto. In an embodiment, the gate dielectric layer 142 may be formed as, for example, a silicon oxide film, a high-κ film, or a combination thereof. The high-κ film may include a material having a higher dielectric constant than the silicon oxide film. For example, the high-κ film may include a material selected from hafnium oxide, hafnium oxynitride, hafnium silicon oxide, lanthanum oxide, lanthanum aluminum oxide, and combinations thereof. However, embodiments of the present inventive concept are not necessarily limited thereto. The gate electrode 145 may include a conductive material, and may include, for example, a metal nitride such as titanium nitride (TiN), tantalum nitride (TaN), or tungsten nitride (WN), and/or a metal material such as aluminum (Al), tungsten (W), molybdenum (Mo), or the like, or a semiconductor material such as doped polysilicon. However, embodiments of the present inventive concept are not necessarily limited thereto. In some embodiments, the gate electrode 145 may be a multilayer including two or more films. In addition, the gate capping layer 147 may include, for example, silicon nitride, silicon oxynitride, silicon carbonitride, or silicon oxycarbonitride. However, embodiments of the present inventive concept are not necessarily limited thereto.

The source/drain region 150 may be disposed on a region of the active pattern 105 positioned on both sides of the gate structure GS. According to an embodiment, the source/drain region 150 may include a first source/drain region 150A disposed on the first active pattern 105a, and a second source/drain region 150B disposed on the second active pattern 105b. For example, the first and second source/drain regions 150A and 150B may have different conductivity types from each other. In an embodiment, the first source/drain region 150A may be a P-type source/drain region 150A, and the second source/drain region 150B may be an N-type source/drain region 150B. However, embodiments of the present inventive concept are not necessarily limited thereto.

The source/drain region 150 may be respectively connected to both end portions of the plurality of channel layers NS in the first direction (e.g., the X direction). The gate electrode 145 may extend in the second direction (e.g., the Y direction) to cross the active pattern 105 while surrounding the plurality of channel layers NS. In an embodiment, the gate electrode 145 may be interposed not only in a space between the gate spacers 141 but also between the plurality of channel layers NS.

Internal spacers IS may be disposed between each of the source/drain region 150 and the gate electrode 145. The internal spacers IS may be disposed on both sides of the gate electrode 145 interposed between the plurality of channel layers NS in the first direction (e.g., the X direction). The plurality of channel layers NS may be respectively connected to the source/drain region 150 on both sides thereof, and the gate electrodes 145 interposed between the plurality of channel layers NS may be electrically insulated from the source/drain region 150 on both sides thereof by the internal spacers IS. The gate dielectric layer 142 may be interposed between the gate electrode 145 and each of the channel layers NS, and may also extend between the gate electrode 145 and the internal spacers IS. As described above, the semiconductor device 100 according to an embodiment may constitute a gate-all-around type field effect transistor.

The source/drain region 150 may include an epitaxial pattern selectively epitaxially grown (SEG) using recessed surface of the active pattern 105 (including side surfaces of the plurality of channel layers NS) on both sides of the gate structure GS as a seed. This source/drain region 150 may be also referred to as a raised source/drain (RSD). For example, in an embodiment the source/drain region 150 may be Si, SiGe, or Ge, and may have either N-type or P-type conductivity. In forming a P-type source/drain region 150, the P-type source/drain region 150 may be re-grown with SiGe, and may be doped with boron (B), indium (In), gallium (Ga), boron trifluoride (BF3), and the like as an example of a P-type impurity. In an embodiment in which silicon (Si) is formed in a N-type source/drain region 150, phosphorus (P), nitrogen (N), arsenic (As), antimony (Sb), or the like may be doped as an N-type impurity, for example. However, embodiments of the present inventive concept are not necessarily limited thereto. The source/drain region 150 may have different shapes in terms of crystallographical stability during a growth process. For example, as illustrated in FIG. 2A, in an embodiment the source/drain region 150 may have a pentagonal cross-section (in the P-type source/drain region 150), but may have a hexagonal cross-section or a polygonal cross-section with gentle angles (in the N-type source/drain region 150).

The interlayer insulating layer 130 may be disposed on the device isolation layer 110. The interlayer insulating layer 130 may be disposed around the gate structure GS while partially covering the source/drain region 150. For example, in an embodiment the interlayer insulating layer 130 may be formed of a flowable oxide (FOX), tonen silazen (TOSZ), an undoped silica glass (USG), a borosilica glass (BSG), a phosphosilaca glass (PSG), a borophosphosilica glass (BPSG), a plasma enhanced tetraethylorthosilicate (PETEOS), a fluoride silicate glass (FSG), a high density plasma (HDP) oxide, a plasma enhanced oxide (PEOX), a flowable CVD (FCVD) oxide, or combinations thereof. However, embodiments of the present inventive concept are not necessarily limited thereto.

The contact structure 180 may pass through the interlayer insulating layer 130, and may be connected to (e.g., directly connected thereto) the source/drain region 150. The contact structure 180 may interconnect the source/drain region 150 and the first interconnection portion ML1 for electrical connection therewith. A separate gate contact structure may be further disposed on the gate electrode 145 in a region. The contact structure 180 may be configured to connect (e.g., electrically connect) the source/drain region 150 and the buried conductive structure 190 to each other. For example, in an embodiment the contact structure 180 may include a first contact portion 180A connected to (e.g., directly connected thereto) the source/drain region 150, and a second contact portion 180B connected to (e.g., directly connected thereto) the buried conductive structure 190. The second contact portion 180B may extend from the first contact portion 180A in the second direction (e.g., the Y direction), and may be easily connected to the buried conductive structure 190.

In an embodiment, the contact structures 180 may include a metal silicide layer positioned on a lower end thereof, and may further include a barrier layer 182 and a plug conductive layer 185, disposed on the metal silicide layer and sidewalls. In an embodiment, the barrier layer 182 may include, for example, a metal nitride such as titanium nitride (TiN), tantalum nitride (TaN), or tungsten nitride (WN). The plug conductive layer 185 may include, for example, a metal material such as aluminum (Al), tungsten (W), molybdenum (Mo), or the like. However, embodiments of the present inventive concept are not necessarily limited thereto. In some embodiments, the number and arrangement of conductive layers constituting the contact structure 180 may be variously changed.

The buried conductive structure 190 may be buried in the interlayer insulating layer 130 and the device isolation layer 110 to be electrically connected to the source/drain region 150. The buried conductive structure 190 may be disposed to electrically connect the contact structure 180 and the power delivery structure 200 to each other. At least a portion of the buried conductive structure 190 may overlap the contact structure 180 in the Z direction, perpendicular to the Y direction and the upper surface of the substrate 101.

In an embodiment, the buried conductive structure 190 may have a side surface that is inclined to decrease in width towards the substrate 101 due to an aspect ratio. For example, the width of the buried conductive structure 190 may decrease (e.g., narrows) towards the power delivery structure 200. However, embodiments of the present disclosure are not necessarily limited thereto. In an embodiment, in the buried conductive structure 190, both side surfaces in the Y direction may include regions having different inclinations from each other. In an embodiment, the buried conductive structure 190 may include a buried conductive layer 195 and a buried insulating liner 192 surrounding a side surface of the buried conductive layer 195.

The buried conductive structure 190 may pass through at least a portion of the device isolation layer 110. The lower surface of the buried conductive structure 190 may be in direct contact with the power delivery structure 200. According to an embodiment, the buried conductive structure 190 may pass through at least a portion of the interlayer insulating layer 130 and at least a portion of the device isolation layer 110, and may extend in the third direction Z. The buried conductive structure 190 may be in direct contact with the power delivery structure 200 in the device isolation layer 110. However, embodiment of the present inventive concept are not necessarily limited thereto. In an embodiment, the buried conductive structure 190 may be buried in the interlayer insulating layer 130 and the device isolation layer 110, may extend into the substrate 101, and may be connected to (e.g., directly connected thereto) the power delivery structure 200.

An upper surface or an upper end of the buried conductive structure 190 may be positioned on a higher level than a level of an upper surface or an upper end of the source/drain region 150. In an embodiment, the buried conductive structure 190 may be in direct contact with the contact structure 180 through the upper surface. However, embodiments of the present disclosure are not necessarily limited thereto, and the buried conductive structure may be directly connected to the first interconnection portion ML1 in some embodiments.

According to an embodiment, the buried conductive structure 190 may include an extension portion 190e extending from one side surface of the buried conductive structure 190 in the second direction Y. For example, the extension portion 190e may extend in the second direction Y towards a portion of the active pattern 105 having a minimum width (e.g., a reduced width) in the second direction Y. Since the extension portion 190e may have a lower surface directly contacting an upper surface of the power delivery structure 200, a contact margin between the buried conductive structure 190 and the power delivery structure 200 may be secured to provide a semiconductor device having increased electrical characteristics.

As illustrated in FIG. 2B, the extension portion 190e may extend in the third direction Z, and may be in direct contact with the upper surface of the power delivery structure 200. The buried conductive structure 190 may include a body portion 190b extending in the X direction. The body portion 190b may include all portions of the buried conductive structure 190 other than the extension portion 190e. The body portion 190b may extend in the third direction Z. The extension portion 190e may extend in the Y direction from one region of at least one side surface of the body portion 190b. According to an embodiment, a width We of the extension portion 190e (e.g., length in the Y direction) may be greater than a width Wb of the body portion 190b (e.g., length in the Y direction). As illustrated in FIG. 2B, a width of the buried conductive structure 190 may decrease towards the power delivery structure 200, and a width Wbb of a lower end of the body portion 190b in the second direction Y may be less than a width Web of a lower end of the extension portion 190e in the second direction Y.

According to an embodiment, the buried conductive structure 190 may include a first extension portion 190ep1 extending towards the first active portion 105_1 (e.g., in the Y direction), and the first extension portion 190ep1 may extend in the third direction Z, and may be connected to (e.g., directly connected thereto) the power delivery structure 200.

According to an embodiment, the buried conductive structure 190 extends in the third direction Z, may include a first region 190_1 having a minimum width, and a second region 190_2 having a width that is greater than the minimum width, and may be connected to the power delivery structure 200 in the second region 190_2, and an active pattern 105 adjacent to the buried conductive structure 190 may include a protruding portion 105p protruding toward the first region 190_1.

The power delivery structure 200 may extend from the lower surface of the substrate 101 towards the upper surface of the substrate 101 (e.g., in the Z direction), to be electrically connected to the buried conductive structure 190. In an embodiment, the power delivery structure 200 may be in direct contact with a bottom surface of the buried conductive structure 190 in the substrate 101. According to an embodiment, the power delivery structure 200 may have a rail shape extending in the first direction X. The power delivery structure 200 may be disposed below the buried conductive structure 190, and may be connected to (e.g., directly connected thereto) a lower end or a lower surface of the buried conductive structure 190. According to an embodiment, the power delivery structure 200 may be in direct contact with the lower surface of the buried conductive layer 195, and may extend in the first direction X. The power delivery structure 200 may form a backside power delivery network (BSPDN) that applies power or ground voltage, and may also be referred to as a buried power rail. For example, the power delivery structure 200 may be a buried interconnection line extending from the bottom of the buried conductive structure 190 in one direction, for example, in the X direction. However, embodiments of the present disclosure are not necessarily limited thereto and a shape of the power delivery structure 200 may vary. In an embodiment, the power delivery structure 200 may be further connected to a buried conductive structure 190 in a different region not shown in the drawings.

The power delivery structure 200 may have side surfaces that are inclined to decrease a width in an upward direction. For example, in an embodiment the power delivery structure 200 may have a trapezoidal shape. The power delivery structure 200 may include a second contact plug 205 and a second insulating liner 202 surrounding a side surface of the second contact plug 205.

In this specification, the buried conductive layer 195 and the buried insulating liner 192, described in the claims, may be referred to as a first contact plug 195 and a first insulating liner 192, respectively.

In an embodiment, at least one of the first contact plug 195 or the second contact plug 205 may include, for example, Cu, Co, Mo, Ru, W, or an alloy thereof. However, embodiments of the present inventive concept are not necessarily limited thereto. In an embodiment, the first contact plug 195 and the second contact plug 205 may include different conductive materials from each other. In some embodiments, the first contact plug 195 may include Mo. The second contact plug 205 may include Cu or W.

The second insulating liner 202 may cover at least a portion of an upper surface and at least a portion of side surfaces of the second contact plug 205. Side surfaces of the second insulating liner 202 may be covered with the lower interlayer insulating layer 210 and the substrate 101.

In an embodiment, at least one of the first insulating liner 192 or the second insulating liner 202 may include, for example, an oxide, a nitride, an oxynitride, SiO₂, SiN, SiCN, SiC, SiCOH, SiON, Al₂O₃, AlN, or a combination thereof. However, embodiments of the present inventive concept are not necessarily limited thereto. The first insulating liner 192 may be disposed to cover at least a portion of side surfaces of the first contact plug 195. The second insulating liner 202 may be disposed to cover at least a portion of side surfaces of the second contact plug 205.

In an embodiment, the buried conductive structure 190 and the power delivery structure 200 may include a conductive barrier. For example, in an embodiment the conductive barrier may include, for example, Ta, TaN, Mn, MnN, WN, Ti, TiN, or a combination thereof, and the conductive barrier may cover a side surface of at least one of the first contact plug 195 or the second contact plug 205. For example, the conductive barrier may be disposed on at least one of between the first insulating liner 192 and the first contact plug 195 or between the second insulating liner 202 and the second contact plug 205.

The plurality of channel layers NS may be disposed on the active patterns 105 to be vertically spaced apart from each other (e.g., in the Z direction). In an embodiment, the semiconductor device 100 may further include the internal spacers IS disposed parallel to the gate electrode 145 between the plurality of channel layers NS. In an embodiment, the semiconductor device 100 may include gate-all-around type transistors in which the gate electrode 145 is disposed between the active patterns 105 and channel layers NS and between the active patterns 105 and the plurality of channel layers NS having a nano-sheet shape. For example, the semiconductor device 100 may include transistors including the channel layers NS, the source/drain region 150, and the gate electrode 145.

The plurality of channel layers NS may be two or more channel layers NS, which may be spaced apart from each other in a direction, perpendicular to upper surfaces of the active patterns 105, for example, in the third direction Z on the active patterns 105. The channel layers NS may be spaced apart from the upper surfaces of the active patterns 105 while being connected to the source/drain region 150. Each of the channel layers NS may have a width that is equal to or similar to a width of each of the active patterns 105 in the second direction Y, and may have a width, equal to or similar to a width of the gate structure GS in the first direction X. In an embodiment in which the internal spacers IS are employed, each of the channel layers NS may have a width that is less than a width between side surfaces in a lower portion of the gate structure GS.

In an embodiment, the plurality of channel layers NS may be formed of a semiconductor material, and may include, for example, at least one of silicon (Si), silicon germanium (SiGe), or germanium (Ge). However, embodiments of the present disclosure are not necessarily limited thereto. The channel layers NS may be formed of, for example, the same material as that of the substrate 101. The number and a shape of the channel layers NS constituting one channel structure may be variously changed in embodiments. For example, in an embodiment, a channel layer may be further disposed in a region in which the active patterns 105 are in direct contact with the gate electrode 145.

The gate structure GS may be disposed to extend over the active regions 105 and the plurality of channel layers NS to cross the active regions 105 and the plurality of channel layers NS. Channel regions of transistors may be formed in the active regions 105 and the plurality of channel layers NS, crossing the gate structure GS. In an embodiment, the gate dielectric layer 142 may be disposed not only between the active region 105 and the gate electrode 145, but also between the plurality of channel layers NS and the gate electrode 145. The gate electrode 145 may be disposed to fill a space between the plurality of channel layers NS on the active regions 105, and extend into an upper portion of the plurality of channel layers NS. The gate electrode 145 may be spaced apart from the plurality of channel layers NS by the gate dielectric layer 142.

In an embodiment, the internal spacers IS may be disposed parallel to the gate electrode 145 between the plurality of channel layers NS (e.g., in the Z direction). The gate electrode 145 may be spaced apart from the source/drain region 150 by the internal spacers IS, and may be electrically separated from each other. In an embodiment, the internal spacers IS may have a shape in which side surfaces of the internal spacers IS facing the gate electrode 145 are flat or convexly rounded inward toward the gate electrode 145. In an embodiment, the internal spacers IS may be formed of an oxide, a nitride, or an oxynitride, and particularly may be formed of a low-K film. In some other embodiments, the semiconductor device 100 may be implemented to include a vertical field effect transistor (FET) in which an active region extending perpendicular to an upper surface of the substrate 101 and a gate structure surrounding the active region are disposed.

The first interconnection portion ML1 may include a plurality of first dielectric layers 171 and 172, a metal interconnection M1, and a metal via V1. The plurality of first dielectric layers 171 and 172 may include first lower and first upper dielectric layers 171 and 172 disposed on the interlayer insulating layer 130. The metal interconnection M1 may be formed in a first upper dielectric layer 172, and the metal via V1 may be formed in a first lower dielectric layer 171. In this embodiment, the metal interconnection M1 may be connected to the contact structure 180 through the metal via V1. According to an embodiment, the metal via V1 may vertically overlap (e.g., overlap in the Z direction) the buried conductive structure 190 on the extension portion 190c.

In an embodiment, the first dielectric layers 171 and 172 may include, for example, at least one of an oxide, a nitride, or an oxynitride, and may include silicon oxide, silicon oxynitride, SiOC, SiCOH, or a combination thereof. However, embodiments of the present disclosure are not necessarily limited thereto. For example, the metal interconnection M1 and the metal via V1 may include copper or a copper-containing alloy. In some embodiments, the metal interconnection M1 and the metal via V1 may be formed together using a dual-damascene process. However, embodiments of the present disclosure are not necessarily limited thereto.

According to an embodiment, the second interconnection portion ML2 connected to the power delivery structure 200 may be disposed on (e.g., disposed directly thereon) the lower surface of the substrate 101. The second interconnection portion ML2 may be an interconnection portion replacing a portion of the first interconnection portion ML1, which may be BEOL. In an embodiment, the second interconnection portion ML2 may be an interconnection portion for power delivery, and the first interconnection portion ML1 may be an interconnection portion for signal transmission. The lower interlayer insulating layer 210 may be disposed on (e.g., disposed directly thereon) the lower surface of the substrate 101, and the second interconnection portion ML2 connected to the power delivery structure 200 may be disposed on (e.g., disposed directly thereon) the lower interlayer insulating layer 210. In a similar manner to the first interconnection portion ML1, the second interconnection portion ML2 may include a plurality of second dielectric layers 271, 272, and 273, metal interconnections M2 and M3, and a metal via V2. However, embodiments of the present inventive concept are not necessarily limited thereto and the number of the second dielectric layers, metal interconnections and metal via may vary.

As such, in an embodiment, a signal network may be configured to pass through the contact structure 180 from the first interconnection portion ML1 disposed on the upper surface of the substrate 101, to be connected to a device region (e.g., the source/drain region 150 and the gate electrode 145), and a power delivery network may be configured to pass through the substrate 101 from the second interconnection portion ML2 disposed on the lower surface of the substrate 101, to be connected to a device region (e.g., the source/drain region 150).

FIG. 2C is a perspective view schematically illustrating some components of a semiconductor device 100a according to an embodiment.

Referring to FIG. 2C, a buried conductive structure 190 may extend in the third direction Z, and may include a first region 190_1 having a minimum width, and a second region 190_2 having a width that is greater than the minimum width. In the first region 190_1, a buried conductive layer 195 may be spaced apart from a power delivery structure 200 by a buried insulating liner 192, and in the second region 190_2, the power delivery structure 200 may be in direct contact with a lower surface of the buried conductive layer 195.

As illustrated in FIG. 2C, a width of the buried conductive structure 190 may decrease toward the power delivery structure 200, and a width Wbb of a lower end of a body portion 190b in the second direction Y may be less than a width Web of a lower end of an extension portion 190e in the second direction Y. In an embodiment in which an aspect ratio of the buried conductive structure 190 is high, a lower end of the buried conductive layer 195 in the body portion 190b of the buried conductive structure 190 may be spaced apart from the power delivery structure 200 (e.g., in the Z direction) by the buried insulating liner 192. Since the semiconductor device 100a of FIG. 2C may be connected to the power delivery structure 200 by the extension portion 190e of the buried conductive structure 190, the power delivery structure 200 may apply power or ground voltage to the buried conductive structure 190.

FIG. 2D is a perspective view schematically illustrating some components of a semiconductor device 100b according to an embodiment. FIG. 2D illustrates a shape and arrangement of a first interconnection portion ML1 including a metal via V1 and a metal interconnection M1, in addition to a buried conductive structure 190 and a power delivery structure 200.

Referring to FIG. 2D, the buried conductive structure 190 of the semiconductor device 100b may not be directly connected to a contact structure 180 (see FIG. 2A), but may be directly connected to the first interconnection portion ML1. According to an embodiment, the metal via V1 may be in direct contact with an upper surface of the buried conductive structure 190 in a region in which an extension portion 190e exists, for example, in a second region 190_2. The metal interconnection M1 may be in direct contact with an upper surface of the metal via V1, and may extend along the buried conductive structure 190 in the first direction X. Since the buried conductive structure 190 may include the extension portion 190e, the metal via V1 may secure a contact margin with the buried conductive structure 190 in the extension portion 190e having a relatively greater width than a body portion 190b in the second direction Y.

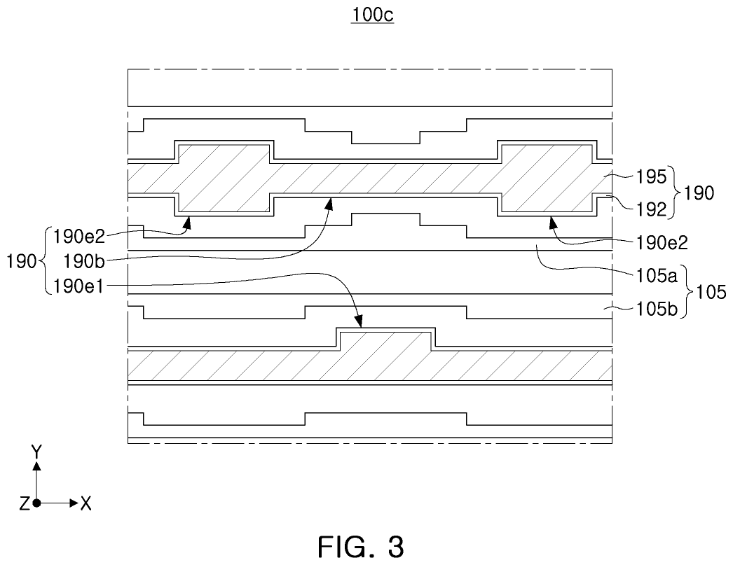

FIG. 3 is a schematic plan view of a semiconductor device 100c according to an embodiment.

Referring to FIG. 3, at least one of first portions 190e1 and at least one of second portions 190e2 may be alternately arranged. For example, in an embodiment, in the second direction Y, the first portions 190e1 and the second portions 190e2 may not overlap each other. However, embodiments of the present disclosure are not necessarily limited thereto.

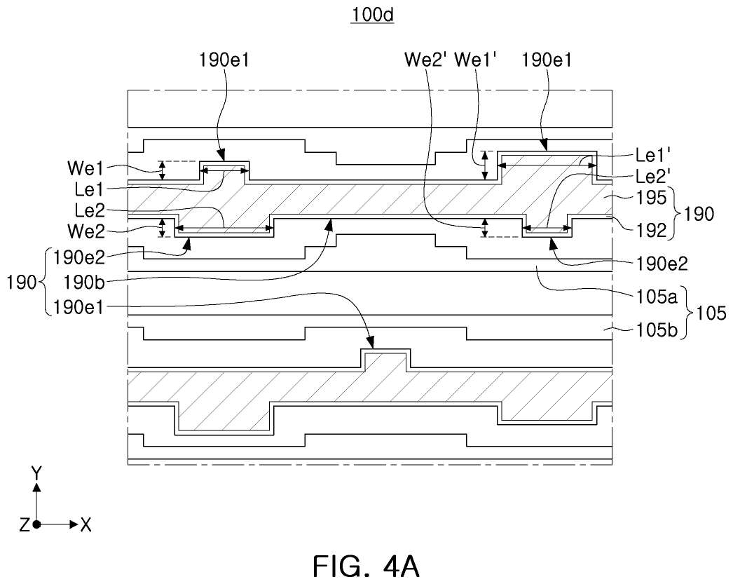

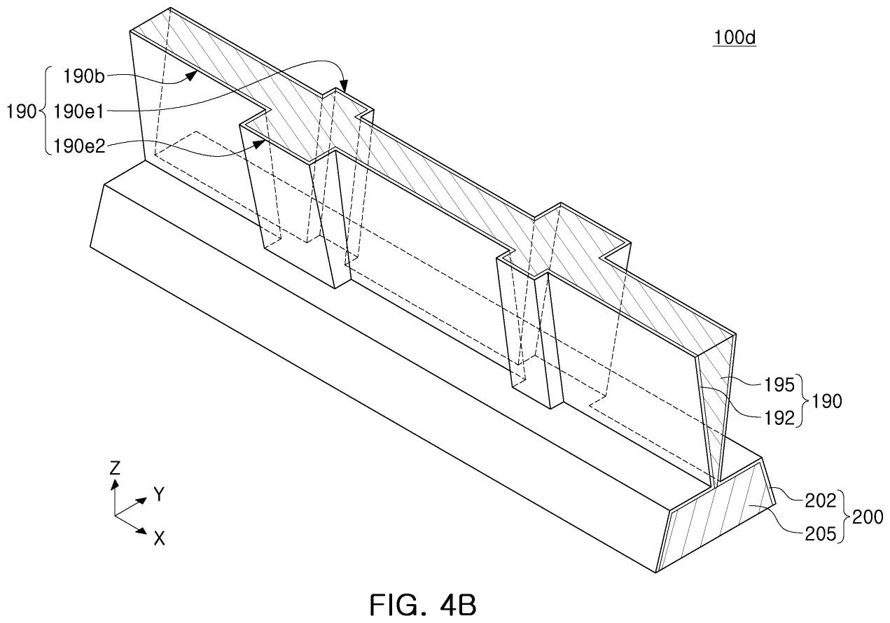

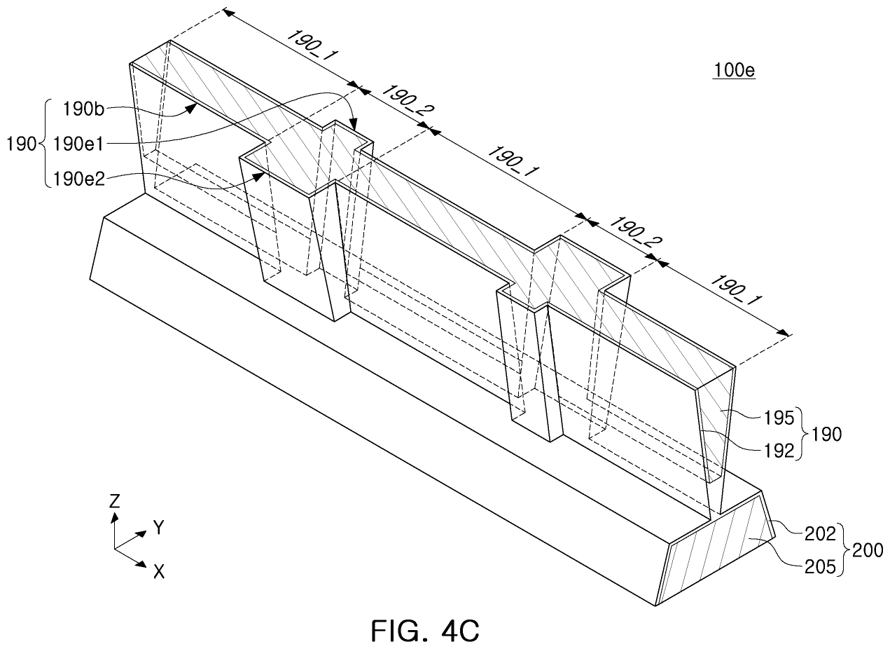

FIG. 4A is a schematic plan view of a semiconductor device 100d according to an embodiment.

FIG. 4B is a perspective view schematically illustrating some components of a semiconductor device 100d according to an embodiment.

Referring to FIGS. 4A and 4B, a buried conductive structure 190 may have a first surface and a second surface, opposing each other (e.g., in the Y direction). An extension portion 190e may include first portions 190e1 extending from the first surface in the second direction Y, and second portions 190e2 extending from the second surface in the second direction Y.

According to an embodiment, at least two of the first portions 190e1 may have different widths Le1 and Le1′ in the first direction X. Also, at least two of the first portions 190e1 may have different widths We1 and We1′ in the second direction Y.

According to an embodiment, widths Le2 and Le2′ of each of the second portions 190e2 in the first direction X may be different from each other, and widths We2 and We2′ of each of the second portions 190e2 in the second direction Y may be different from each other.

According to an embodiment, at least one of the first portions 190e1 and at least one of the second portions 190e2 may overlap each other in the second direction Y. A first portion 190e1 and a second portion 190e2 overlapping in the second direction Y may have the widths Le1 and Le1′ of the first portion 190e1 in the first direction X and the widths Le2 and Le2′ of the second portion 190e2 in the first direction X, having different sizes, respectively. The first portion 190e1 and the second portion 190e2 overlapping in the second direction Y may have the widths We1 and We1′ of the first portion 190e1 in the second direction Y) and the widths We2 and We2′ of the second portion 190e2 in the second direction Y, having different sizes, respectively.

According to an embodiment, at least one of the first portions 190e1 and at least one of the second portions 190e2 may be alternately arranged with respect to each other. In this embodiment, the first portion 190e1 and the second portion 190e2 may not overlap each other in the second direction Y.

FIG. 4C is a perspective view schematically illustrating some components of a semiconductor device 100e according to an embodiment.

Referring to FIG. 4C, a buried conductive structure 190 of FIG. 4C has substantially the same characteristics as the buried conductive structure 190 of FIG. 2C described above, except for the description with reference to FIGS. 4A and 4B. For example, in a first region 190_1, a buried conductive layer 195 may be spaced apart from a power delivery structure 200 (e.g., in the Z direction) by a buried insulating liner 192, and in a second region 190_2, the power delivery structure 200 may be in direct contact with a lower surface of the buried conductive layer 195.

FIG. 5A is a schematic plan view of a semiconductor device 100f according to an embodiment. FIG. 5B is a perspective view schematically illustrating some components of a semiconductor device 100f according to an embodiment.

Referring to FIGS. 5A and 5B, at least one of a first active pattern 105a or a second active pattern 105b may include a first active portion 105_1 having a first width Da1, and a second active portion 105_2 having a second width Da2, greater than the first width Da1. According to an embodiment, at least one of the first active pattern 105a or the second active pattern 105b may further include a third active portion 105_3 having a third width Da3, greater than the second width Da2.

According to an embodiment, a buried conductive structure 190 may include a first extension portion 190ep1 extending towards the first active portion 105_1 (e.g., in the Y direction) and a second extension portion 190ep2 extending towards the second active portion 105_2 (e.g., in the Y direction). The buried conductive structure 190 further may include a body portion 190b, in addition to the first extension portion 190ep1 and the second extension portion 190ep2, and the second extension portion 190ep2 may extend in the third direction Z, and may be connected to a power delivery structure 200.

Referring to FIG. 5B, a width Web1 of a lower end of the first extension portion 190ep1 in the second direction Y may be greater than a width Web2 of a lower end of the second extension portion 190ep2 in the second direction Y, and the width Web2 of the lower end of the second extension portion 190ep2 in the second direction Y may be greater than a width Web3 of a lower end of the body portion 190b in the second direction Y.

FIG. 5C is a perspective view schematically illustrating some components of a semiconductor device 100g according to an embodiment.

Referring to FIG. 5C, a buried conductive structure 190 of FIG. 5C has substantially the same characteristics as the buried conductive structure 190 of FIG. 2C described above, except for the description with reference to FIGS. 5A and 5B. For example, in a first region 190_1, a buried conductive layer 195 may be spaced apart from a power delivery structure 200 by a buried insulating liner 192, and in a second region 190_2, the power delivery structure 200 may be in direct contact with a lower surface of the buried conductive layer 195.

FIG. 6 is schematic cross-sectional views illustrating a semiconductor device 100h according to an embodiment.

Referring to FIG. 6, unlike the semiconductor device 100 of FIG. 1B, a lower interlayer insulating layer 210 may be disposed instead of a substrate 101, and an uppermost portion of the lower interlayer insulating layer 210 may be positioned on a level that is higher than a lowermost portion of a device isolation layer 110. In an embodiment in which a back grinding process to be described later is performed, the substrate 101 may be completely removed from the device isolation layer 110. Thereafter, the semiconductor device of FIG. 6 may be provided through a process of forming the lower interlayer insulating layer 210, a process of forming a power delivery structure 200, and a process of forming a second interconnection portion ML2.

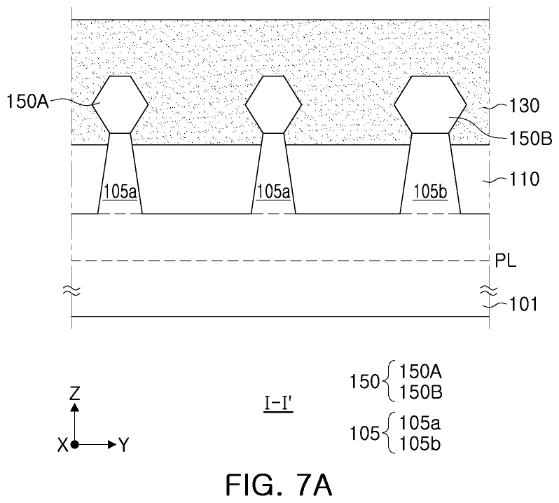

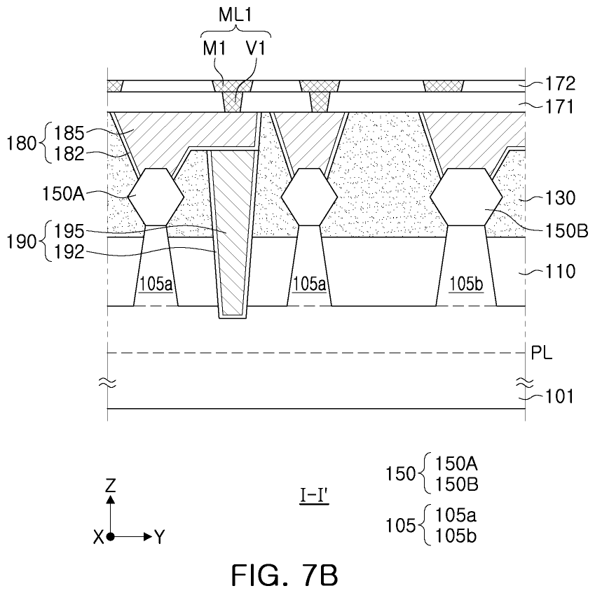

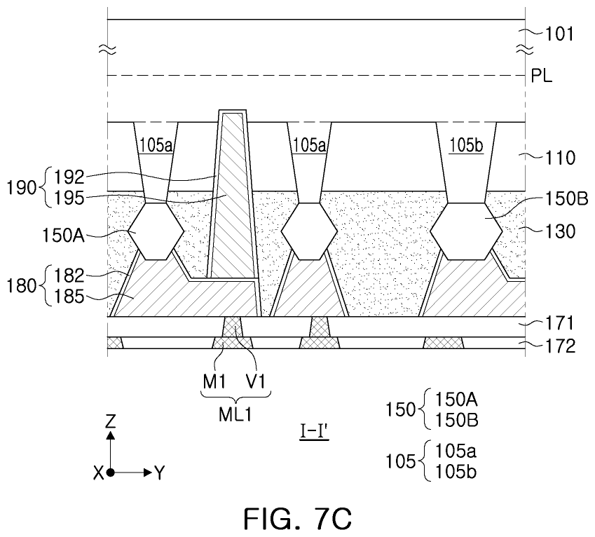

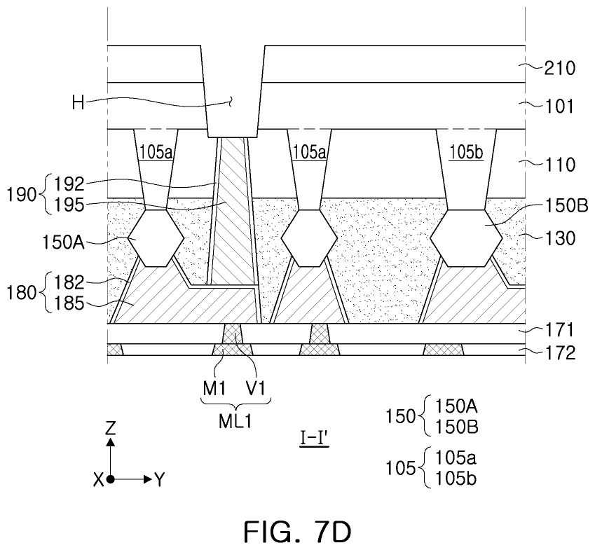

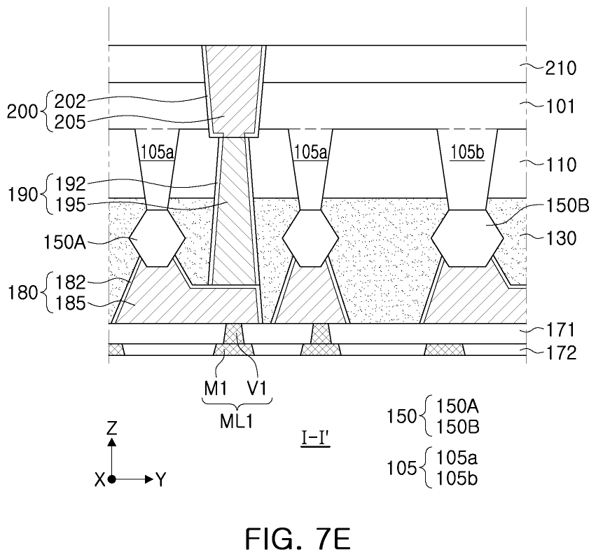

FIGS. 7A, 7B, 7C, 7D and 7E are cross-sectional views illustrating a method of manufacturing a semiconductor device 100 according to embodiments in a process sequence. FIGS. 7A, 7B, 7C, 7D and 7E respectively illustrate cross-sectional views of the semiconductor device 100 of FIG. 1B, taken along line I-I′. Hereinafter, it can be understood that terms such as ‘on,’ ‘upper,’ ‘upper portion,’ ‘upper surface,’ ‘below,’ ‘lower,’ ‘lower portion,’ ‘lower surface,’ ‘side surface,’ and the like may be denoted by reference numerals and refer to the drawings, except in which otherwise indicated.

Referring to FIG. 7A, a gate-all-around type field effect transistor may be formed on an upper surface of a substrate 101. For example, the gate-all-around type field effect transistor may include an active pattern 105, a plurality of channel layers NS stacked on the active pattern 105 to be spaced apart from each other (e.g., in the Z direction), a gate structure GS crossing the active pattern 105, and a source/drain region 150 disposed on the active pattern 105 on both sides of the gate structure GS and connected to both side surfaces of the plurality of channel layers NS. An interlayer insulating layer 130 may be further formed to cover the source/drain region 150 and the gate structure GS.

Referring to FIG. 7B, a buried conductive structure 190, a contact structure 180, and a first interconnection portion ML1 may be formed. The buried conductive structure 190 passing through a portion of a device isolation layer 110 and a portion of the substrate 101 may be formed. In an embodiment, the buried conductive structure 190 may be formed by filling a remaining space with a first contact plug 195, after a first insulating liner 192 is formed. A contact hole connected to (e.g., directly connected thereto) the source/drain region 150 and the buried conductive structure 190 may be formed in the interlayer insulating layer 130, a barrier layer 182 and a plug conductive layer 185 may be sequentially formed to fill the contact hole. A planarization process such as CMP may be performed such that an upper surface of the contact structure 180 is substantially coplanar with an upper surface of the interlayer insulating layer 130 (e.g., in the Z direction). The first interconnection portion ML1 connected to (e.g., directly connected thereto) the contact structure 180 may be formed on the interlayer insulating layer 130.

Referring to FIG. 7C, the substrate 101 may be turned over (e.g., inverted), and a back grinding process may be performed on the upper surface of the substrate 101. In FIG. 7C, for ease of understanding, it is illustrated that the structure illustrated in FIG. 7B is bonded in a mirror image. To reduce a thickness of the substrate 101, a back grinding process may be performed on the upper surface and a lower surface of the substrate 101. For example, in an embodiment a back grinding process may be performed up to a portion marked as “PL.”

Referring to FIG. 7D, a lower interlayer insulating layer 210 may be formed on the substrate 101 (e.g., formed directly thereon in the Z direction), and a hole H may be formed. The lower interlayer insulating layer 210 for passivation may be formed on the upper surface of the substrate 101, and the hole H may be formed in the lower interlayer insulating layer 210 and the substrate 101. In a process of forming the hole H, a portion of the first insulating liner 192 of the buried conductive structure 190 may be removed to partially expose the first contact plug 195.

Referring to FIG. 7E, a second insulating liner 202 may be formed on an inner surface of the hole H, and a second contact plug 205 may be formed to fill the hole H.

The second insulating liner 202 may be conformally deposited on the upper surface of the substrate 101 as well as the inner surface of the hole H. For example, in an embodiment a deposition process may be formed by an atomic layer deposition (ALD) process, a chemical vapor deposition (CVD) process, or a physical vapor deposition (PVD) process. A portion of an upper surface of the first contact plug 195 may the be exposed by selectively removing a portion of the second insulating liner 202 located on a bottom surface of the hole H.

After depositing a conductive material such that the second contact plug 205 may be filled in the hole H, a planarization process such as CMP may then be performed to remove a material disposed on the lower interlayer insulating layer 210 together. As a result, the power delivery structure 200 extending from the upper surface of the substrate 101 and connected to the buried conductive structure 190 may be formed.

Referring to FIG. 2A together, the semiconductor device 100 illustrated in FIG. 2A may be manufactured by forming a second interconnection portion ML2 connected to the power delivery structure 200 in a subsequent process.

Through this process, as a result, a contact margin between the buried conductive structure 190 and the power delivery structure 200 may be secured.

According to embodiments, an active pattern adjacent to a buried conductive structure may include a protruding portion protruding toward the buried conductive structure, and a contact margin between the buried conductive structure and a power delivery structure may be secured by an extension portion extending from one side surface of the buried conductive structure, to provide a semiconductor device having an increased degree of integration and increased electrical characteristics.

Various advantages and effects of embodiments of the present inventive concept are not necessarily limited to the above description.

While non-limiting embodiments have been illustrated and described above, it will be apparent to those skilled in the art that modifications and variations could be made without departing from the scope of the present inventive concept.

What is claimed is:

1. A semiconductor device comprising:
a substrate;
an active region on the substrate and including an active pattern extending in a first direction;
a device isolation layer on the substrate, the device isolation layer surrounding the active pattern;
a gate structure extending in a second direction intersecting the first direction;
a source/drain region disposed on the active pattern on both sides of the gate structure;
an interlayer insulating layer on the device isolation layer, the interlayer insulating layer at least partially covering the gate structure and the source/drain region;
a contact structure passing through the interlayer insulating layer, the contact structure is connected to the source/drain region;
a buried conductive structure extending in the first direction, the buried conductive structure is electrically connected to the contact structure, the buried conductive structure passes through the interlayer insulating layer and the device isolation layer to extend in a third direction perpendicular to the first and second directions; and
a power delivery structure extending from a lower surface of the substrate towards an upper surface of the substrate, the power delivery structure is electrically connected to the buried conductive structure,
wherein the buried conductive structure includes a body portion extending in the first direction, and an extension portion extending from a region of at least one side surface of the body portion in the second direction towards the active pattern.

2. The semiconductor device of claim 1, wherein:
the extension portion extends towards a portion of the active pattern having a minimum width in the second direction; and
the extension portion has a lower surface directly contacting an upper surface of the power delivery structure.

3. The semiconductor device of claim 1, wherein:
the buried conductive structure comprises a buried conductive layer and a buried insulating liner surrounding a side surface of the buried conductive layer;
the body portion extends in the third direction, and
a lower end of the buried conductive layer is spaced apart from the power delivery structure by the buried insulating liner in the body portion.

4. The semiconductor device of claim 2, wherein:
a width of the buried conductive structure narrows towards the power delivery structure; and
a width of a lower end of the body portion in the second direction is less than a width of a lower end of the extension portion in the second direction.

5. The semiconductor device of claim 1, wherein:
the buried conductive structure comprises a buried conductive layer and a buried insulating liner surrounding a side surface of the buried conductive layer,
wherein the power delivery structure is in direct contact with a lower surface of the buried conductive layer and extends in the first direction.

6. The semiconductor device of claim 1, further comprising:
a first interconnection portion disposed on the interlayer insulating layer, the first interconnection portion including a metal via connected to the buried conductive structure, the metal via is electrically connected to the contact structure; and
a second interconnection portion connected to the power delivery structure on a lower surface of the buried conductive structure,
wherein the metal via vertically overlaps the buried conductive structure on the extension portion.

7. The semiconductor device of claim 1, wherein:
the buried conductive structure has a first surface and a second surface opposite the first surface;
the extension portion includes first portions extending in the second direction from the first surface, and second portions extending in the second direction from the second surface;
widths of the first portions in the first direction are different from each other; and
widths of the first portions in the second direction are different from each other.

8. The semiconductor device of claim 7, wherein:
widths of the second portions in the first direction are different from each other; and
widths of the second portions in the second direction are different from each other.

9. The semiconductor device of claim 7, wherein at least one of the first portions and at least one of the second portions are alternately arranged with respect to each other.

10. The semiconductor device of claim 1, wherein:
the buried conductive structure extends into the substrate through the device isolation layer; and
the buried conductive structure is in direct contact with the power delivery structure in the substrate.

11. The semiconductor device of claim 1, further comprising:
a plurality of channel layers on the active pattern, the plurality of channel layers are spaced apart from each other in a direction perpendicular to the upper surface of the substrate,
wherein the gate structure includes a gate electrode extending in the second direction and surrounding each of the plurality of channel layers, and a gate dielectric layer disposed between the plurality of channel layers and the gate electrode.

12. The semiconductor device of claim 1, wherein the extension portion extends in the second direction towards a portion of the active pattern having a minimum width in the second direction.

13. A semiconductor device comprising:
a substrate;
a first active pattern and a second active pattern on the substrate, the first and second active patterns extending in a first direction;
a device isolation layer on the substrate, the device isolation layer surrounding the first and second active patterns;
a gate structure extending in a second direction intersecting the first direction;
a first source/drain region on the first active pattern on both sides of the gate structure;
a second source/drain region on the second active pattern on both sides of the gate structure;
an interlayer insulating layer on the device isolation layer, the interlayer insulating layer at least partially covering the gate structure and the first and second source/drain regions;
a contact structure passing through the interlayer insulating layer, the contact structure is connected to each of the first and second source/drain regions;
a buried conductive structure extending in the first direction, the buried conductive structure is connected to the contact structure, the buried conductive structure passes through at least a portion of the interlayer insulating layer and at least a portion of the device isolation layer to extend in a third direction perpendicular to the first and second directions; and
a power delivery structure extending from a lower surface of the substrate towards an upper surface of the substrate, the power delivery structure is electrically connected to the buried conductive structure,
wherein at least one of the first active pattern or the second active pattern includes a first active portion having a first width and a second active portion having a second width greater than the first width,
the buried conductive structure includes a first extension portion extending towards the first active portion, and
the first extension portion extends in the third direction and is connected to the power delivery structure.

14. The semiconductor device of claim 13, further comprising:
a first active region extending in the first direction, the first active region having the first active pattern; and
a second active region extending in the first direction, the second active region having the second active pattern,
wherein the first and second source/drain regions have different conductivity types from each other.

15. The semiconductor device of claim 13, wherein:
a first side surface of the first active pattern and a first side surface of the second active pattern are relatively flat;
a second side surface of the first active pattern that is opposite to the first side surface of the first active pattern comprises a curved portion; and
a second side surface of the second active pattern opposite to the first side surface of the second active pattern comprises a curved portion.

16. The semiconductor device of claim 13, wherein:
at least one of the first active pattern or the second active pattern further comprises a third active portion having a third width greater than the second width; and
the buried conductive structure comprises a second extension portion extending towards the second active portion.

17. The semiconductor device of claim 16, wherein:
the buried conductive structure further comprises a body portion comprising all portions of the buried conductive structure except for the first extension portion and the second extension portion; and
the second extension portion extends in the third direction and is connected to the power delivery structure.

18. The semiconductor device of claim 17, wherein:
a width of a lower end of the first extension portion in the second direction is greater than a width of a lower end of the second extension portion in the second direction; and
the width of the lower end of the second extension portion in the second direction is greater than a width of a lower end of the body portion in the second direction.

19. A semiconductor device comprising:
a substrate;
an active region extending on the substrate in a first direction, the active region including an active pattern;
a device isolation layer on the substrate, the device isolation layer surrounding the active pattern;
a plurality of channel layers stacked on the active pattern, the plurality of channel layers are spaced apart from each other;
a gate structure on the active pattern, the gate structure extending in a second direction intersecting the first direction, the gate structure surrounding the plurality of channel layers;
a source/drain region on the active pattern on both sides of the gate structure;
an interlayer insulating layer on the device isolation layer, the interlayer insulating layer at least partially covering the gate structure and the source/drain region;
a contact structure passing through the interlayer insulating layer, the contact structure is connected to the source/drain region;
a buried conductive structure extending in the first direction, the buried conductive structure is connected to the contact structure, the buried conductive structure passes through at least a portion of the interlayer insulating layer and at least a portion of the device isolation layer; and
a power delivery structure extending from a lower surface of the substrate towards an upper surface of the substrate, the power delivery structure is electrically connected to the buried conductive structure,
wherein the buried conductive structure extends in a third direction perpendicular to the first and second directions, the buried conductive structure includes a first region having a minimum width and a second region having a width greater than the minimum width, the buried conductive structure is connected to the power delivery structure in the second region, and
the active pattern adjacent to the buried conductive structure includes a protruding portion protruding towards the first region.

20. The semiconductor device of claim 19, wherein:
the buried conductive structure comprises a buried conductive layer and a buried insulating liner surrounding a side surface of the buried conductive layer,
the buried conductive layer is spaced apart from the power delivery structure by the buried insulating liner in the first region; and
the power delivery structure is in direct contact with a lower surface of the buried conductive layer in the second region.
